(19) United States
(12) Patent Application Publication
(10) Pub. No.: US 2023/0246124 A1
(43) Pub. Date: Aug. 3, 2023

(54) QUANTUM WELL STRUCTURE AND PREPARATION METHOD THEREFOR, AND LIGHT-EMITTING DIODE

(71) Applicant: ENKRIS SEMICONDUCTOR, INC., Suzhou (CN)

(72) Inventors: Weihua LIU, Wuxi (CN); Kai CHENG, Suzhou (CN)

(73) Assignee: ENKRIS SEMICONDUCTOR, INC., Suzhou (CN)

(21) Appl. No.: 18/185,723

(22) Filed: Mar. 17, 2023

Related U.S. Application Data
(63) Continuation of application No. PCT/CN2020/131127, filed on Nov. 24, 2020.

(51) Int. Cl. H01L 33/06; H01L 33/32; H01L 33/10; H01L 33/00

(52) U.S. Cl. CPC H01L 33/06; H01L 33/10; H01L 33/0075; H01L 33/325

(57) ABSTRACT

Disclosed are a quantum well structure and a preparation method therefor, and a light-emitting diode. The quantum well structure includes at least one quantum well and at least one first film layer. The quantum well includes a well layer and a barrier layer alternately stacked, and the well layer includes a first doping element. Each first film layer includes a second doping element. The second doping element is used for adjusting a doping content of the first doping element in the well layer. The first doping element includes at least one of In and Al, and the second doping element includes at least one of Al, Mg, and Si. A content of the first doping element may be adjusted by catalysis of the second doping element, thereby adjusting light-emitting efficiency and a light wavelength of the quantum well as required.

### CROSS-REFERENCE TO RELATED APPLICATIONS

This application is a continuation of International Application No. PCT/CN2020/131127, filed on Nov. 24, 2020, the disclosure of which is hereby incorporated by reference in its entirety.

### TECHNICAL FIELD

Embodiments of the present disclosure relate to the field of light-emitting diode technologies, and in particular, to a quantum well structure and a preparation method therefor, and a light-emitting diode.

### BACKGROUND

For a semiconductor light-emitting diode (LED), electrons and holes injected are used to emit light in quantum well through radiative recombination. A specific film layer of the quantum well needs to be doped with a specific element, and a doping content of the specific element may directly affect a wavelength range of an emitted light.

However, due to a current structure design of the quantum well, the doping content of the specific element is limited, which makes it difficult for LED to realize long wavelength luminescence.

### SUMMARY

In view of this, embodiments of the present disclosure provide a quantum well structure and a preparation method therefor, and a light-emitting diode based on the quantum well structure.

According to a first aspect, the present disclosure provides a quantum well structure, including: at least one quantum well and at least one first film layer. Each of the at least one quantum well includes a well layer and a barrier layer alternately stacked, and the well layer includes a first doping element. Each of the at least one first film layer includes a second doping element. The second doping element is used for adjusting a doping content of the first doping element in the well layer adjacent to the each of the at least one first film layer. The first doping element includes at least one of In and Al, and the second doping element includes at least one of Al, Mg, and Si.

Light-emitting efficiency and light wavelength of the quantum well structure are related to the doping content of the first doping element in the well layer. By providing the first film layer including the second doping element, a content of the first doping element doped into the well layer when the well layer is formed may be adjusted (for example, increased or decreased) by catalysis of the second doping element, thereby adjusting the light-emitting efficiency and the light wavelength of the quantum well as required.

For example, in an embodiment of the first aspect of the present disclosure, a thickness of the first film layer is less than a thickness of an atomic layer, and the first film layer is in a discontinuous island-like state or a porous film-like state, so that a quantum dot structure with different content of the first doping element in island-like regions or film-porous regions of the first film layer may be formed. Therefore, by the catalysis of the second doping element in the first film layer, a growth mode of the well layer may be changed and then the content of the first doping element may be adjusted.

For example, according to the quantum well structure provided in an embodiment of the first aspect of the present disclosure, at least one of the well layers is provided with one first film layer, of the at least one first film layer, arranged on a side of the at least one of the well layers, and the at least one of the well layers is grown on the first film layer.

In this way, the well layer is in contact with the first film layer, that is, when the first doping element is doped in the well layer after the well layer is grown, a catalytic effect of the second doping element is significant since a distance between the well layer and the second doping element in the first film layer is close, thereby improving an adjusting effect (for example, increasing or decreasing) of the doping content of the first doping element.

For example, according to the quantum well structure provided in an embodiment of the first aspect of the present disclosure, at least one of the well layers is provided with two first film layers, of the at least one first film layer, arranged on both sides of the at least one of the well layers.

In this way, by providing two first film layers doped with the second doping element on both sides of the well layer, when the first doping element is doped in the well layer, the catalytic effect of the second doping element is more significant, thereby improving the adjusting effect (for example, increasing or decreasing) of the doping content of the first doping element.

For example, according to the quantum well structure provided in an embodiment of the first aspect of the present disclosure, at least one of the barrier layers is inserted by one first film layer of the at least one first film layer, and a distance between the first film layer and a well layer adjacent to the first film layer is less than or equal to 2 nm.

In this way, an incorporated content of the second doping element in the well layer formed on the barrier layer may be adjusted, by inserting the first film layer into the barrier layer, without affecting lattice difference between the well layer and the barrier layer.

For example, according to the quantum well structure provided in an embodiment of the first aspect of the present disclosure, a content of the second doping element in the first film layer changes in a gradual type or in a stepped type, and a content of the second doping element in an area, of the first film layer, close to a well layer, adjacent to the first film layer, is greater than a content of the second doping element in an area, of the first film layer, away from the well layer adjacent to the first film layer.

In this way, an adverse effect on other film layers (such as the barrier layer) caused by too much first doping element contained in the part, far from the well layer, of the first film layer may be avoided, with ensuring that the part, close to the well layer, of the first film layer contains enough second doping element to adjust the doping content of the first doping element in the well layer.

For example, according to the quantum well structure provided in an embodiment of the first aspect of the present disclosure, the second doping element includes at least one of Al and Mg, and the second doping element is used for increasing the doping content of the first doping element in the well layer adjacent to the each of the at least one first film layer.

For example, the second doping element is Al, a thickness of the first film layer is less than a thickness of an atomic layer, and the first film layer is in a discontinuous island-like state or a porous film-like state.

It should be noted that the thickness of the atomic layer is determined based on a type of atoms and a lattice structure formed.

In this way, the second doping element has an effect of forward catalysis, and may increase an incorporated content of the first doping element during doping, so that the quantum well structure may achieve a function of emitting light with a longer electroluminescent wavelength.

For example, according to the quantum well structure provided in an embodiment of the first aspect of the present disclosure, the second doping element includes Si, and the doping content of the second doping element is used for reducing the doping content of the first doping element in the well layer adjacent to the each of the at least one first film layer.

In this way, the second doping element has an effect of reverse catalysis, and may reduce the incorporated content of the first doping element during doping, so that the quantum well structure may achieve a function of emitting light with a shorter electroluminescent wavelength.

For example, according to the quantum well structure provided in an embodiment of the first aspect of the present disclosure, the well layer includes at least one of InGaN and AlGaN; and the at least one first film layer includes at least one of AlInGaN and MgInGaN.

For example, according to the quantum well structure provided in an embodiment of the first aspect of the present disclosure, a material component ratio, in the well layer, of the first doping element to Ga ranges from 0:100 to 40:60; and a material component ratio, in the at least one first film layer, of a sum of In and Ga to the second doping element ranges from 80:20 to 99:1.

For example, according to the quantum well structure provided in an embodiment of the first aspect of the present disclosure, the at least one first film layer includes a plurality of first film layers, the at least one quantum well includes a plurality of quantum wells alternately stacked; and at least one quantum well of the plurality of quantum wells is grown on each of the plurality of first film layers.

According to a second aspect, an embodiment of the present disclosure provides a light-emitting diode including: a substrate; an N-type layer arranged on the substrate; a P-type layer arranged on a side, away from the substrate, of the N-type layer; and a quantum well structure according to the embodiments of the first aspect. The quantum well structure is disposed between the N-type layer and the P-type layer. In a direction from the N-type layer to the P-type layer, the well layer and the barrier layer in each of the quantum well are stacked in sequence.

For example, according to the light-emitting diode provided in an embodiment of the second aspect of the present disclosure, the light-emitting diode further includes a u-type layer located between the N-type layer and the substrate, where the u-type layer may be a u-type GaN film layer.

For example, according to the light-emitting diode provided in an embodiment of the second aspect of the present disclosure, a plurality of grooves are provided in the N-type layer, and each of the plurality of grooves is provided with a Distributed Bragg Reflector mirror (DBR) structure and/or a photonic crystal structure.

According to a third aspect, an embodiment of the present disclosure provides a preparation method for a quantum well structure, including: forming a barrier layer; forming a first film layer stacked on the barrier layer, where the first film layer includes a second doping element, and the second doping element includes at least one of Al, Mg, and Si; and forming a well layer on the first film layer, where the well layer includes a first doping element, the second doping element is used for adjusting a doping content of the first doping element in the well layer adjacent to the first film layer, and the first doping element includes at least one of In and Al.

### BRIEF DESCRIPTION OF THE DRAWINGS

To illustrate technical solutions of the embodiments of the present disclosure or the prior art more clearly, accompanying drawings used in the embodiments of the present disclosure and the prior art will be briefly introduced below. Obviously, the accompanying drawings described below are only some embodiments of the present disclosure. For those skilled in the art, other relevant drawings may also be obtained based on these drawings without any inventive efforts.

FIG. 1 is a schematic cross-sectional view of a quantum well structure according to an embodiment of the present disclosure.

FIG. 2 is another schematic cross-sectional view of a quantum well structure according to an embodiment of the present disclosure.

FIG. 3 is still another schematic cross-sectional view of a quantum well structure according to an embodiment of the present disclosure.

FIG. 4 is yet still schematic cross-sectional view of a quantum well structure according to an embodiment of the present disclosure.

FIG. 5 is a schematic cross-sectional view of a light-emitting diode according to an embodiment of the present disclosure.

FIG. 6 is a schematic plane-structural diagram of a light-emitting module according to an embodiment of the present disclosure.

FIG. 7 is a flowchart of a preparation method for a quantum well structure according to an embodiment of the present disclosure.

### DETAILED DESCRIPTIONS OF THE EMBODIMENTS

The technical solutions in the embodiments of the present disclosure will be clearly and completely described below with reference to the accompanying drawings in the embodiments of the present disclosure. Apparently, the described embodiments are only a part of the embodiments of the present disclosure, but not all of the embodiments. Based on the embodiments in the present disclosure, all other embodiments obtained by those skilled in the art without creative efforts shall fall within the protection scope of the present disclosure.

GaN-based LED may be used for display and illumination, and related applications. In a quantum well of the LED, a lattice constant difference between a well layer and a barrier layer and the like may cause a defect in an epitaxial film layer. Moreover, it is difficult to effectively control an incorporated content of a doping element in the well layer in subsequent doping processes, such as a doping process to the well layer. For example, It is difficult to control an incorporated content of In component in the well layer composed of the InGaN material to exceed 40%. Even if the incorporated content of In component is more than 40%, material quality may decrease significantly, leading to a decline in the internal quantum effect. In view of this, an embodiment of the present disclosure provides a quantum well structure and a preparation method therefor, and a light-emitting diode, to solve the above technical problems.

According to a quantum well structure provided in an embodiment of the present disclosure, the quantum well structure includes: at least one quantum well and at least one first film layer. Each of the quantum well includes a well layer and a barrier layer alternately stacked, and the well layer includes a first doping element. Each of the first film layer includes a second doping element. The second doping element is used for adjusting a doping content of the first doping element in the well layer adjacent to the first film layer. The first doping element includes at least one of In and Al, and the second doping element includes at least one of Al, Mg, and Si. Light-emitting efficiency and light wavelength of the quantum well structure are related to the doping content of the first doping element in the well layer. By providing the first film layer including the second doping element, a content of the first doping element doped into the well layer when the well layer is formed may be adjusted (for example, increased or decreased) by catalysis of the second doping element, thereby adjusting the light-emitting efficiency and the light wavelength of the quantum well as required.

For example, in an embodiment of the present disclosure, a thickness of the first film layer is less than a thickness of an atomic layer, and the first film layer is in a discontinuous island-like state or a porous film-like state, so that a quantum dot structure with different content of the first doping element in island-like regions or film-porous regions of the first film layer may be formed. Therefore, by the catalysis of the second doping element in the first film layer, a growth mode of the well layer may be changed and then the content of the first doping element may be adjusted.

A quantum well structure and a preparation method therefor, and a light-emitting diode according to at least one embodiment of the present disclosure will be described in detail with reference to the accompanying drawings. In these accompanying drawings, a space rectangular coordinate system is established based on a plane where the well layer is located to illustrate the quantum well structure and the preparation method therefor, and a position of each film layer in the light-emitting diode. In the space rectangular coordinate system, X axis and Y axis are parallel to the plane where the well layer is located, and Z axis is perpendicular to the plane where the well layer is located.

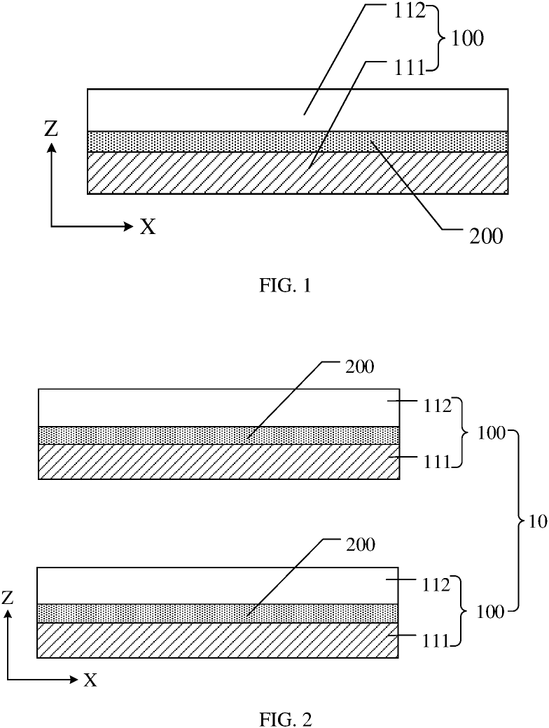

In an embodiment of the present disclosure, as shown in FIG. 1, the quantum well structure includes a quantum well 100 and a first film layer 200. The quantum well 100 includes a barrier layer 111 and a well layer 112 alternately stacked, the well layer 112 includes a first doping element (for example, at least one of In and Al), and the first film layer 200 includes a second doping element (for example, at least one of Al, Mg, and Si). The second doping element is used for adjusting a doping content of the first doping element in the well layer 112 adjacent to the first film layer 200. In practical operation, the first film layer 200 may include Al and the first film layer 200 may be AlInGaN. The first film layer 200 may be used for electron diffusion and lattice transition, and may buffer a growth of the well layer 112 with releasing stress of the well layer 112, thereby improving the internal quantum efficiency of the well layer 112, greatly improving the light-emitting brightness of the quantum well structure, and improving the light-emitting efficiency. In the quantum well structure provided by some embodiments of the present disclosure, the well layer may include InGaN. Polarization matching between the first film layer 200 of the pressent disclosure and the well layer 112 may be adjusted through the second doping element Al, which is conducive to assembling In element on a contacting interface between the well layer 112 and the first film layer 200, adjusting a growth mode of the well layer 112, and increasing a density of the In element in the InGaN well layer 112 (in the embodiment of the present disclosure, the higher density means a higher content). That is, the second doping element is used to adjust the doping content of the first doping element in the well layer 112 adjacent to the first film layer 200, therefore the light-emitting efficiency and the light wavelength of the quantum well may be adjusted as required.

In another embodiment of the present disclosure, the second doping element of the first film layer 200 may be the Si element. Because of the existence of Si element, a lattice constant of the first film layer 200 is smaller than that of the well layer 112, and does not match the lattice constant of the well layer 112, which is not conducive to assembling In element on a contacting interface between the well layer 112 and the first film layer 20 when the well layer 112 is epitaxially grown on the first film layer 200. The growth mode of the well layer 112 is adjusted by the second doping element Si in the first film layer 200 of the present disclosure to reduce density of the In element in the InGaN well layer 112 (in an embodiment of the present disclosure, the higher density means the higher content), and shorten light-emitting wavelength of the quantum well structure That is, the second doping element is used to adjust the doping content of the first doping element in the well layer 112 adjacent to the first film layer 200, therefore the light-emitting efficiency and the light wavelength of the quantum well may be adjusted as required.

For example, in an embodiment of the present disclosure, the quantum well structure may include a plurality of first film layers and a plurality of quantum wells. Exemplarily, as shown in FIG. 2, a plurality of quantum wells 100 and a plurality of first film layers 200 are alternately stacked. For example, each adjacent quantum well 100 and first film layer 200 serve as a cycle unit, and a quantum well structure 10 may include a plurality of cycle units alternately stacked.

It should be noted that in a whole preparation process of the quantum well structure, when the well layer in the quantum well is formed on the first film layer, a formation sequence of the well layer and the potential barrier layer, and a position relationship between the well layer, the potential barrier layer and the first film layer are not limited. For example, the well layer may be directly formed on the surface of the first film layer; or after the first film layer is formed, another film layer (such as a barrier layer) may form on the first film layer, and then a well layer may be grown on the other film layer in the subsequent process. Several different quantum well structures will be described through several specific examples below.

For example, according to a quantum well structure provided by an embodiment of the present disclosure, at least one of the well layer is provided with one of the first film layer and the first film layer is arranged on a side of the well layer, and at least one of the well layer is grown on the first film layer. In this way, the well layer is in contact with the first film layer, that is, when the first doping element is doped in the well layer after the well layer is grown, a catalytic effect of the second doping element is significant since a distance between the well layer and the second doping element in the first film layer is close, thereby improving an adjusting effect (for example, increasing or decreasing) of the doping content of the first doping element.

Exemplarily, as shown in FIG. 1, after the barrier layer 111 is formed, the first film layer 200 is epitaxially grown on the barrier layer 111, and the second doping element is doped in the first film layer 200, then the well layer 112 is epitaxially grown on the first film layer 200, and the first doping element is doped in the well layer 112. Thereby, the barrier layer 111 may be further epitaxially grown on the well layer 112, and then the above process flow may be repeated in the subsequent process to obtain the quantum well structure including a plurality of the quantum wells and a plurality of the first film layers.

For example, according to the quantum well structure shown in FIG. 1, in each cycle unit, the first film layer 200 may be formed first, and then the well layer 112 may be formed on the first film layer 200, and the well layer 111 may be formed on the well layer 112.

For example, according to a quantum well structure provided by an embodiment of the present disclosure, at least one of the well layer is provided with two of the first film layers and the two first film layers are disposed on both sides of the well layer. In this way, by providing two first film layers doped with the second doping element on both sides of the well layer symmetrically, when the first doping element is doped in the well layer, the catalytic effect of the second doping element is more significant, thereby improving the adjusting effect (for example, increasing or decreasing) of the doping content of the first doping element.

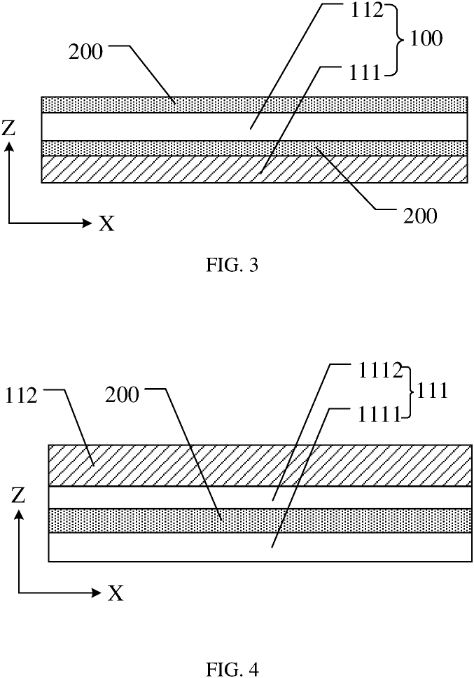

Exemplarily, as shown in FIG. 3, in each cycle unit, a first film layer 200 may be formed first, a well layer 112 may be formed on the first film layer 200, and then another first film layer 200 may be formed on the well layer 112. In this embodiment, the first film layer 200 may include Al element, the first film layer may be AlInGaN, and the well layer 112 may include InGaN. The first film layer 200 below the well layer 112 (a side of the well layer 112 facing the substrate) may adjust the polarization match with the well layer 112 by the second doping element Al, which is conducive to the assembling of the In element on the contact interface between the well layer 112 and the first film layer 200, to adjust the growth mode of the well layer 112, and to increase the density of the In element in the InGaN well layer 112. The first film layer 200 above the well layer 112 (a side of the well layer 112 away from the substrate) contains Al element, so that a threshold voltage between the well layer 112 and the barrier layer 111 may be increased, and efficiency of recombination between electron hole pairs on a electron transition path without current injection may be reduced, thereby improving light-emitting efficiency of the quantum well.

As shown in FIG. 3, the barrier layer 111 may be formed before or after the first film layer 200, the well layer 112 and the another first film layer 200 are stacked in layers.

For example, according to a quantum well structure provided by an embodiment of the present disclosure, at least one of the barrier layer is inserted by one of the first film layer. For example, a distance between the first film layer and an adjacent well layer is less than or equal to 2 nm. In this way, an incorporated content of the second doping element in the well layer formed on the barrier layer may be adjusted, by inserting the first film layer into the barrier layer, without affecting lattice difference between the well layer and the barrier layer.

Exemplarily, as shown in FIG. 4, in each cycle unit, a first film layer 200 is inserted into a barrier layer 111. For example, the barrier layer 111 includes a first sub-barrier layer 1111 and a second sub-barrier layer 1112. In a preparation process of each cycle unit, the first sub-barrier layer 1111 may be formed first, the first film layer 200 may be epitaxially grown on the first sub-barrier layer 1111, the second sub-barrier layer 1112 may be epitaxially grown on the first film layer 200, and then a well layer 112 may be epitaxially grown on the second sub-barrier layer 1112.

In an embodiment of the present disclosure, a content distribution of the second doping element in the first film layer may be adjusted to control an incorporated content of the first doping element in the well layer formed in subsequent processes.

For example, according to a quantum well structure provided by an embodiment of the present disclosure, a content of the second doping element in the first film layer changes in a gradual type or in a stepped type, and a content of the second doping element in an area of the first film layer close to an adjacent well layer is greater than a content of the second doping element in an area of the first film layer away from the adjacent well layer. In this way, an adverse effect on other film layers (such as the barrier layer) caused by too much first doping element contained in the part, far from the well layer, of the first film layer may be avoided, with ensuring that the part, close to the well layer, of the first film layer contains enough second doping element to adjust the doping content of the first doping element in the well layer.

For example, according to quantum well structures provided by some embodiments of the present disclosure, the second doping element includes at least one of Al and Mg, and the second doping element is used to increase a doping content of the first doping element in the well layer adjacent to the first film layer. In this way, the second doping element has an effect of forward catalysis, and may increase an incorporated content of the first doping element during doping, so that the quantum well structure may achieve a function of emitting light with a longer electroluminescent wavelength.

For example, according to other quantum well structures provided by some embodiments of the present disclosure, the second doping element includes Si, and the doping content of the second doping element is used to reduce the doping content of the first doping element in the well layer adj acent to the first film layer. In this way, the second doping element has an effect of reverse catalysis, and may reduce the incorporated content of the first doping element during doping, so that the quantum well structure may achieve a function of emitting light with a shorter electroluminescent wavelength.

A quantum well structure may be grown on a wafer, and a preparation process needs to be controlled because wafer is heated unevenly during growing process. If temperature of an area is low and content of the first doping element is too much, a reverse catalyst may be used in the area to reduce a doping content of the first doping element; if temperature of an area is high, which is not conducive to incorporation of the first doping element, a forward catalyst may be used in this area.

For example, according to quantum well structures provided by some embodiments of the present disclosure, the well layer includes at least one of InGaN and AlGaN; and the at least one first film layer includes at least one of AlInGaN and MgInGaN.

For example, according to quantum well structures provided by some embodiments of the present disclosure, a material component ratio of the first doping element to Ga in the well layer ranges from 0:100 to 40:60, such as 10:90, 20:80, 30:70 and so on. And in the at least one first film layer, a material component ratio of a sum of In and Ga to the second doping element ranges from 80:20 to 99:1, such as 90:10, 95:5, 97:3 and so on.

An embodiment of the present disclosure provides a light-emitting diode including: a substrate, an N-type layer, a P-type layer and a quantum well structure according to the embodiments described above. The N-type layer is arranged on the substrate. The P-type layer arranged on a side, away from the substrate, of the N-type layer. The quantum well structure is disposed between the N-type layer and the P-type layer. In a direction from the N-type layer to the P-type layer, the well layer and the barrier layer in each of the quantum well are stacked in sequence.

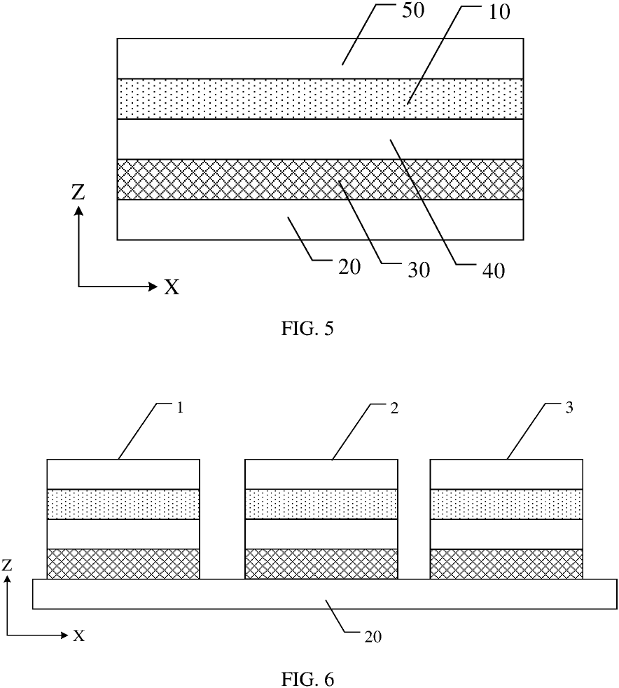

Exemplarily, as shown in FIG. 5, the light-emitting diode includes a quantum well structure 10, a substrate 20, an N-type layer 40 and a P-type layer 50. The N-type layer 40, the quantum well structure 10 and the P-type layer 50 are stacked on the substrate 20 in sequence. The N-type layer 40 may be an N-type GaN layer, and the P-type layer 50 may be a P-type GaN layer.

For example, the substrate 20 may be any one of a sapphire substrate, a GaN-based substrate, a Si-based substrate, a SiC-based substrate, a SiN-based substrate, or a glass substrate.

For example, according to the light-emitting diode provided in an embodiment of the present disclosure, a plurality of grooves may be provided in the N-type layer, and a Distributed Bragg Reflector mirror (DBR) structure and/or the photonic crystal structure may be set in each of the plurality of grooves. The DBR structure and/or the photonic crystal structure may be used for filtering light in a specific wavelength range, thereby improving a monochromatic level of the light emitted by the light-emitting diode. The DBR structure is composed of at least two kinds of semiconductor materials or dielectric materials grown alternately. The DBR structure may be used for acquiring high reflectivity for waves in a certain frequency range (that is, the light in a certain wavelength range). Photonic crystal is a periodic dielectric structure with photonic band-gap (PBG) property. In this periodic structure, waves in a certain frequency range cannot be transmitted.

For example, according to the light-emitting diode provided in an embodiment of the present disclosure, the light-emitting diode may further include a u-shaped layer. Exemplarily, as shown in FIG. 5, a u-type layer 30 is located between the N-type layer 40 and the substrate 20. For example, the u-type layer 30 may be a u-type GaN film layer.

For example, in an embodiment of the present disclosure, the light-emitting diode may further include a buffer layer located between the substrate 20 and the N-type layer 40. For example, a material of the buffer layer may include one or more of AlN, GaN, AlGaN and InGaN. The buffer layer may greatly relieve stress that occurs when the epitaxial layer is grown on the silicon substrate, and realize dislocation filtering, thereby improving crystal quality of the epitaxial layer. For example, the buffer layer may also act as a flattening layer. When the buffer layer is formed on the substrate, a surface of the light-emitting diode including the substrate is flattened to improve the flattening of the subsequently prepared N-type layer, the film layer in the quantum well structure, and the P-type layer, to ensure preparation yield of the light-emitting diode.

An embodiment of the present disclosure provides a light-emitting module including a plurality of light-emitting diodes, where the light-emitting diode may be the light-emitting diode in the above embodiments. For example, the plurality of light-emitting diodes are configured to emit light of at least two colors. For example, the light-emitting module is configured to emit red, green and blue light, and adjacent light-emitting diodes that emitting different colors are combined into a unit, so that the unit may emit white light, colored light and light of other color as required. For example, further, the light-emitting module may be used in the display field, and the unit may be used as a display unit (that is, the pixel) for displaying images.

For example, according to an embodiment of the present disclosure, the light-emitting module may be a display panel. For example, as shown in FIG. 6, the light-emitting module (display panel) includes three types of light-emitting diodes 1, 2, and 3. The light-emitting diodes 1, 2, and 3 are configured to emit light of three colors (such as red, green, and blue) respectively. The adjacent light-emitting diodes 1, 2, and 3 work as a display unit (pixel), and the light-emitting diodes 1, 2, and 3 are used as sub-pixels respectively.

In an embodiment of the present disclosure, the light-emitting module (display panel) may be used in the augmented reality (AR) or virtual reality (VR) display field. Exemplarily, the light-emitting module is used for AR glasses including optical waveguide lenses and an optical module. The light emitted by the light-emitting module (that is, the displayed image) enters the optical waveguide lenses after passing through the optical module (for example, including magnifying glass and so on), and then the light is introduced into the human eyes by the optical waveguide lenses. Meanwhile, the image of the surrounding environment may be observed by human eyes through the optical waveguide lenses. In this way, the display image observed by the human eyes may be projected into an environment image to realize the augmented reality display.

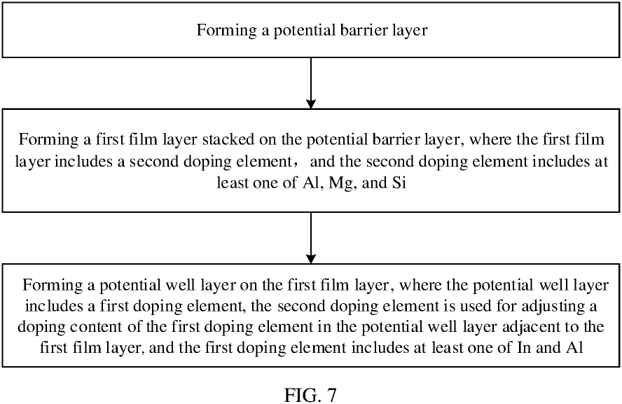

An embodiment of the present disclosure provides a preparation method for a quantum well structure, as shown in FIG. 7, the method includes: forming a barrier layer; forming a first film layer stacked on the barrier layer, where the first film layer includes a second doping element, and the second doping element includes at least one of Al, Mg, and Si; and forming a well layer on the first film layer, where the well layer includes a first doping element, the second doping element is used for adjusting a doping content of the first doping element in the well layer adjacent to the first film layer, and the first doping element includes at least one of In and Al. Light-emitting efficiency and wavelength of the quantum well structure are related to a doping content of the first doping element in the well layer. In the preparation method, by providing the first film layer including the second doping element described above, a content of the first doping element doped into the well layer when the well layer is formed may be adjusted (for example, increased or decreased) by catalysis of the second doping element, thereby adjusting the light-emitting efficiency and the light wavelength of the quantum well as required. A specific structure of the quantum well structure obtained by the preparation method may be obtained with reference to relevant description in the above embodiments, and the details are not described herein again.

The above embodiments are only the preferred embodiments of the present disclosure, and not intended to limit the scope protected by the present disclosure. Any modification, equivalent replacement, improvement, and so on, made in the spirit and principle of the present disclosure shall fall into the scope protected by the present disclosure.

What is claimed is:

1. A quantum well structure, comprising:
at least one quantum well, wherein each of the at least one quantum well comprises a well layer and a barrier layer alternately stacked, the well layer comprises a first doping element, and the first doping element comprises at least one of In and Al; and
at least one first film layer, wherein each of the at least one first film layer comprises a second doping element, the second doping element is used for adjusting a doping content of the first doping element in a well layer adjacent to the each of the at least one first film layer, and the second doping element comprises at least one of Al, Mg and Si.

2. The quantum well structure according to claim 1, wherein at least one of the well layers is provided with one first film layer, of the at least one first film layer, arranged on a side of the at least one of the well layers, and the at least one of the well layers is grown on the first film layer.

3. The quantum well structure according to claim 1, wherein at least one of the well layers is provided with two first film layers, of the at least one first film layer, arranged on both sides of the at least one of the well layers.

4. The quantum well structure according to claim 1, wherein at least one of the barrier layers is inserted by one first film layer of the at least one first film layer, and a distance between the first film layer and a well layer adjacent to the first film layer is less than or equal to 2 nm.

5. The quantum well structure according to claim 2, wherein a content of the second doping element in the first film layer changes in a gradual type or in a stepped type, and a content of the second doping element in an area, of the first film layer, close to a well layer adjacent to the first film layer, is greater than a content of the second doping element in an area, of the first film layer, away from the well layer adjacent to the first film layer.

6. The quantum well structure according to claim 1, wherein the second doping element comprises at least one of Al and Mg, and the second doping element is used for increasing the doping content of the first doping element in the well layer adjacent to the each of the at least one first film layer; or
the second doping element comprises Si, and the second doping element is used for reducing the doping content of the first doping element in the well layer adjacent to the each of the at least one first film layer.

7. The quantum well structure according to claim 1, wherein the well layer comprises at least one of InGaN and AlGaN; and
the at least one first film layer comprises at least one of AlInGaN and MgInGaN.

8. The quantum well structure according to claim 7, wherein
a material component ratio, in the well layer, of the first doping element to Ga ranges from 0: 100 to 40:60; and
a material component ratio, in the at least one first film layer, of a sum of In and Ga to the second doping element ranges from 80:20 to 99:1.

9. The quantum well structure according to claim 1, wherein
the at least one first film layer comprises a plurality of first film layers, the at least one quantum well comprises a plurality of quantum wells alternately stacked; and
at least one quantum well of the plurality of quantum wells is grown on each of the plurality of first film layers.

10. A light-emitting diode, comprising:
a substrate;
an N-type layer arranged on the substrate;
a P-type layer arranged on a side, away from the substrate, of the N-type layer; and
the quantum well structure according to claim 1, disposed between the N-type layer and the P-type layer, wherein the well layer and the barrier layer, in each of the at least one quantum well, are stacked in sequence, in a direction from the N-type layer to the P-type layer.

11. The light-emitting diode according to claim 10, further comprising a u-type layer located between the N-type layer and the substrate, wherein the u-type layer is a u-type GaN film layer.

12. The light-emitting diode according to claim 10, wherein a plurality of grooves are provided in the N-type layer, and each of the plurality of grooves is provided with a Distributed Bragg Reflector mirror (DBR) structure and/or a photonic crystal structure.

13. A preparation method for a quantum well structure, comprising:
forming a barrier layer;
forming a first film layer stacked on the barrier layer, wherein the first film layer comprises a second doping element, and the second doping element comprises at least one of Al, Mg, and Si; and
forming a well layer on the first film layer, wherein the well layer comprises a first doping element, the second doping element is used for adjusting a doping content of the first doping element in the well layer adjacent to the first film layer, and the first doping element comprises at least one of In and Al.
